(19) United States
(12) Patent Application Publication
(10) Pub. No.: US 2016/0343976 A1
(43) Pub. Date: Nov. 24, 2016

(54) OLED PACKAGE STRUCTURE AND PACKAGE METHOD THEREOF

(71) Applicant: SHENZHEN CHINA STAR OPTOELECTRONICS TECHNOLOGY CO., LTD., Shenzhen, Guangdong (CN)

(72) Inventors: Weijing ZENG, Shenzhen, Guangdong (CN); Taipi WU, Shenzhen, Guangdong (CN)

(73) Assignee: Shenzhen China Star Optoelectronics Technology Co., Ltd., Shenzhen, Guangdong (CN)

(21) Appl. No.: 14/424,922

(22) PCT Filed: Feb. 9, 2015
(86) PCT No.: PCT/CN2015/072480

§ 371 Date: Feb. 27, 2015

(30) Foreign Application Priority Data
Dec. 4, 2014 (CN) 201410734373.1

(51) Int. Cl. H01L 51/52; H01L 51/56

(52) U.S. Cl. CPC H01L 51/5246; H01L 51/56; H01L 51/5259

(57) ABSTRACT

The present invention provides an OLED package structure and package method thereof, and the structure comprises a package cover plate (1), a substrate (2), oppositely positioned with the package cover plate (1), an OLED element (21), positioned between the package cover plate (1) and the substrate (2) and set on the substrate (2), dryer (12), positioned at periphery of the OLED element (21) between the package cover plate (1) and the substrate (2), seal (13), positioned at periphery of the dryer (12) to bond the package cover plate (1) and the substrate (2) and frit glass (11), located at periphery of the seal (13) to bond the package cover plate (1) and the substrate (2); the structure utilizes the seal and the frit glass together to implement the package to make the package structure possess well tightness and mechanical strength at the same time, and meanwhile, the dryer filler is located at the periphery of the OLED element, which applies to the OLED element packages of both top emitting type and bottom emitting type.

### FIELD OF THE INVENTION

The present invention relates to a display skill field, and more particularly to an OLED package structure and a package method thereof.

### BACKGROUND OF THE INVENTION

An OLED is an Organic Light Emitting Diodes Display possessing properties of self-illumination, high brightness, wide view angle, high contrast, flexibility and low power consumption, etc., and accordingly has been received more attentions. As being the display of next generation, it has been gradually replaced traditional liquid crystal displays and widely applied in cellular phone screens, computer displays, full color TV, etc. OLED display technology is different from the traditional liquid crystal display technology and the back light is not required. It utilizes an ultra thin organic material coating layer and a glass substrate, and theses organic material will illuminate when the current is conducted. Because the organic material can easily react with water and oxygen, the OLED display panel has extremely high demands for the package as being the display element based on the organic material.

Most of the organic materials of the OLED emitting layer are highly sensitive to the pollution, water vapor and oxygen in the atmosphere. In the environment containing water vapor, the electric chemical corrosion can easily occur and cause damage to the OLED element. Therefore, it is crucially important for the steady lighting of the OLED element to be isolated from external environment as possible as it can by promoting the tightness of the element interior by package of the OLED element.

At present, common package methods are: 1, the package seal combines the dryer, i.e. an indentation with a certain depth is etched at specific position of the package cover plate, and the absorbent sheet (dryer sheet) is attached in the indentation, and a circle of UV curing glue is coated outside the effective display area. This package process is well developed, and material is specific. However, the procedure is complicated and only for bottom emitting element. Besides, the package efficiency is lower. 2, Laser sealing is to form frit glass on the package cover plate, and the laser beam is moved to melt the glass glue at the seal area. After cooling of the melted glass, the sealed package space is formed between the package cover plate and the substrate to be packaged. The tightness of this package method is good but there are restrictions for the width and height of the glue due to the influence of the laser energy distribution. Besides, during the laser melting, stress is generated as the glass glue is heated. After the glass glue is melted and cooled to form the fixed package structure with the package cover plate and the substrate to be packaged, an internal residual stress of the package structure can make the dehiscence or the peeling of the package structure happen. Thus, the tightness of the package structure can be failed.

### SUMMARY OF THE INVENTION

An objective of the present invention is to provide an OLED package structure, utilizing the seal and the frit glass together to implement the package possessing well tightness and mechanical strength at the same time, and meanwhile, the dryer filler is merely located at the periphery of the effective lighting area, which applies to the OLED element packages of both top emitting type and bottom emitting type.

Another objective of the present invention is to provide an OLED package method, as utilizing the frit glass to implement the package and meanwhile, combining the seal for package, to increase the bonding area of the package cover plate and the substrate for reducing the dehiscence or the peeling of the glass glue caused by an internal residual stress as packaging, and tightness is promoted and mechanical strength is raised in advance.

For realizing the aforesaid objectives, the present invention provides an OLED package structure, comprising a package cover plate, a substrate, oppositely positioned with the package cover plate, an OLED element, positioned between the package cover plate and the substrate and set on the substrate, dryer, positioned at periphery of the OLED element between the package cover plate and the substrate, seal, positioned at periphery of the dryer to bond the package cover plate and the substrate and frit glass, located at periphery of the seal to bond the package cover plate and the substrate.

The OLED element comprises an anode conductive layer located on the substrate, an organic layer located on the anode conductive layer and a cathode conductive layer located on the organic layer.

An indentation is formed on the package cover plate corresponding to a location of the OLED element, and an internal space of the indentation accommodates a dimension of the OLED element.

The dryer is polymer material containing absorbent composition, and a gap between the dryer and the frit glass is larger than or equal to 500 um.

The seal is UV seal, and a gap between the seal and the dryer is smaller than or equal to 500 um.

The present invention provides an OLED package method, comprising steps of:

step 1, providing a package cover plate and a substrate;

an OLED element is located on the substrate, and an indentation is formed on the package cover plate corresponding to a location of the OLED element, and an internal space of the indentation accommodates a dimension of the OLED element;

step 2, coating a circle of glass glue on the cover package plate, and forming frit glass by high temperature presintering;

step 3, coating a circle of dryer on the package cover plate at an inner side of the frit glass and at an outer side of the indentation, and curing the dryer by low temperature baking;

step 4, coating a circle of seal at an inner side of the frit glass and at an outer side of the dryer;

step 5, oppositely laminating the package cover plate and the substrate under a vacuum condition, and curing the seal by UV irradiation;

step 6, melting the frit glass by laser irradiation, and bonding the package cover plate and the substrate to accomplish the package of the package cover plate to the substrate.

In the step 1, both the package cover plate and the substrate are glass substrates, and the OLED element comprises an anode conductive layer located on the substrate, an organic layer located on the anode conductive layer and a cathode conductive layer located on the organic layer.

In the step 2, screen print or dispensing is employed to coat the glass glue on the package cover plate.

In the step 3, the dryer is polymer material containing absorbent composition, and a gap between the dryer and the frit glass is larger than or equal to 500 um.

In the step 4, the seal is UV seal, and a gap between the seal and the dryer is larger than or equal to 500 um.

The present invention further provides an OLED package structure, comprising a package cover plate, a substrate, oppositely positioned with the package cover plate, an OLED element, positioned between the package cover plate and the substrate and set on the substrate, dryer, positioned at periphery of the OLED element between the package cover plate and the substrate, seal, positioned at periphery of the dryer to bond the package cover plate and the substrate and frit glass, located at periphery of the seal to bond the package cover plate and the substrate;

wherein the OLED element comprises an anode conductive layer located on the substrate, an organic layer located on the anode conductive layer and a cathode conductive layer located on the organic layer;

wherein an indentation is formed on the package cover plate corresponding to a location of the OLED element, and an internal space of the indentation accommodates a dimension of the OLED element.

The benefits of the present invention are: the OLED package structure utilizes the seal and the frit glass together to implement the package for possessing well tightness and mechanical strength at the same time, and meanwhile, the dryer filler is located at the periphery of the OLED element, which applies to the OLED element packages of both top emitting type and bottom emitting type. The OLED package method of the present invention utilizes the frit glass to implement the package and meanwhile, combines advantages of the seal for package. The seal can increase the bonding area of the package cover plate and the substrate for reducing the dehiscence or the peeling of the glass glue caused by an internal residual stress as packaging, and mechanical strength is raised in advance. Meanwhile, the dryer filler is located at the periphery of the OLED element, which the package method applies to the OLED element packages of both top emitting type and bottom emitting type.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structural diagram of an OLED element according to the present invention;

FIG. 2 is a diagram of an OLED package structure of an OLED element according to the present invention;

FIG. 3 is a flowchart of an OLED package method according to the present invention;

FIG. 4 is a diagram of the step 1 according to the OLED package method of the present invention;

FIG. 5 is a diagram of the step 2 according to the OLED package method of the present invention;

FIG. 6 is a diagram of the step 3 according to the OLED package method of the present invention;

FIG. 7 is a diagram of the step 4 according to the OLED package method of the present invention;

FIG. 8 is a diagram of the step 5 according to the OLED package method of the present invention;

FIG. 9 is a diagram of the step 6 according to the OLED package method of the present invention.

### DETAILED DESCRIPTION OF PREFERRED EMBODIMENTS

For better explaining the technical solution and the effect of the present invention, the present invention will be further described in detail with the accompanying drawings and the specific embodiments.

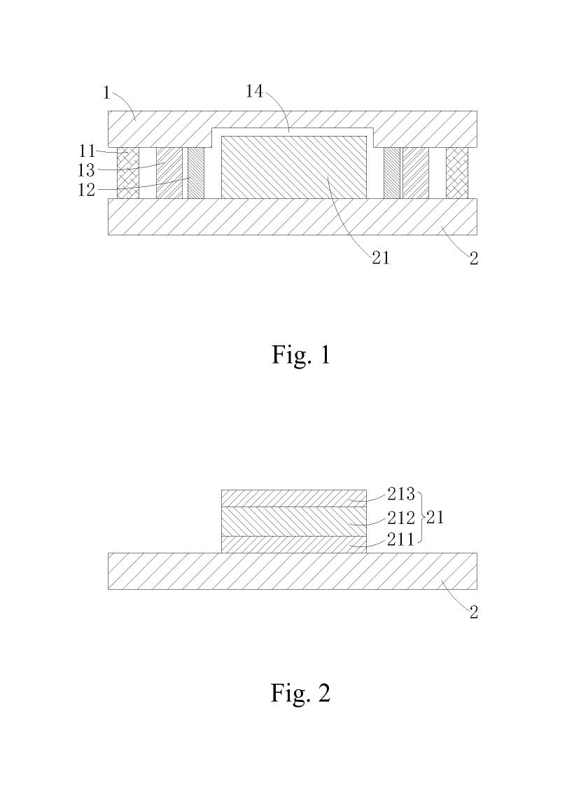

Please refer to FIG. 1 and FIG. 2. The present invention provides an OLED package structure, comprising a package cover plate 1, a substrate 2, oppositely positioned with the package cover plate 1, an OLED element 21, positioned between the package cover plate 1 and the substrate 2 and set on the substrate 2, dryer 12, positioned at periphery of the OLED element 21 between the package cover plate 1 and the substrate 2, seal 13, positioned at periphery of the dryer 12 to bond the package cover plate 1 and the substrate 2 and frit glass 11, located at periphery of the seal 13 to bond the package cover plate 1 and the substrate 2.

Furthermore, as shown in FIG. 2, the OLED element 21 comprises an anode conductive layer 211 located on the substrate 2, an organic layer 212 located on the anode conductive layer 211 and a cathode conductive layer 213 located on the organic layer 212.

As shown in FIG. 1, an indentation 14 is formed on the package cover plate 1 corresponding to a location of the OLED element 21, and an internal space of the indentation 14 accommodates a dimension of the OLED element 21 for accepting the OLED element 21.

With utilizing the frit glass 11 to implement the package, the tightness of the OLED package is effectively raised.

The dryer 12 is polymer material containing absorbent composition, and a gap between the dryer 12 and the frit glass 11 is larger than or equal to 500 um. By locating the dryer 12 at periphery of the OLED element 21, the OLED package structure of the present invention applies to the OLED element packages of both top emitting type and bottom emitting type.

The seal 13 is UV seal, and preferably, a gap between the seal 13 and the dryer 12 is smaller than or equal to 500 um. The seal 13 is employed to increase the bonding area of the package cover plate and the substrate for reducing the dehiscence or the peeling of the glass glue caused by an internal residual stress as packaging, and mechanical strength is raised in advance.

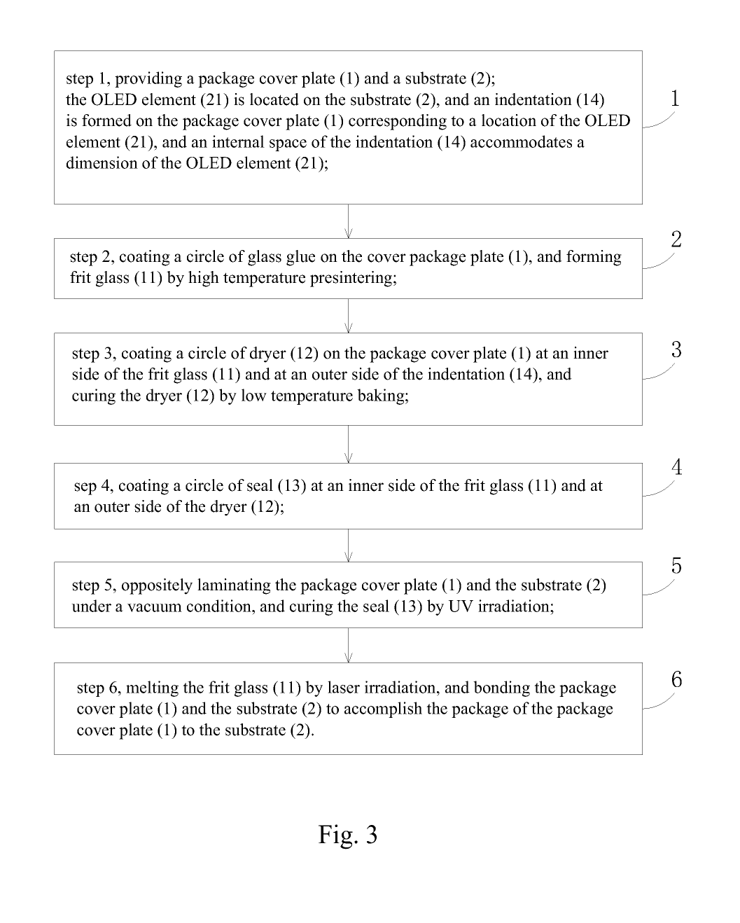

Please refer to FIG. 3. The present invention provides an OLED package method, comprising steps of:

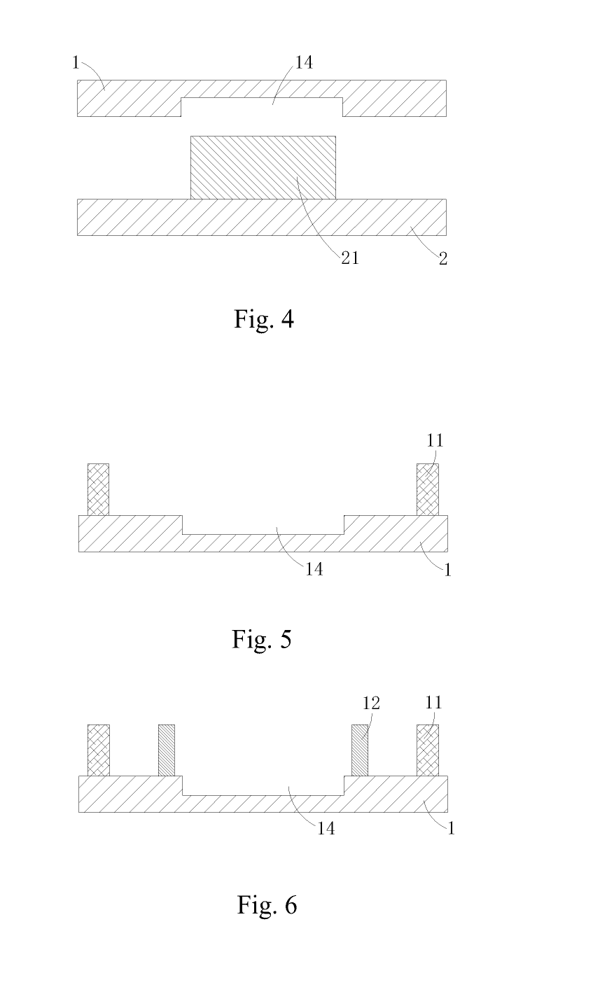

step 1, as shown in FIG. 4, providing a package cover plate 1 and a substrate 2.

The OLED element 21 is located on the substrate 2, and an indentation 14 is formed on the package cover plate 1 corresponding to a location of the OLED element 21, and an internal space of the indentation 14 accommodates a dimension of the OLED element 21. Preferably, both the package cover plate 1 and the substrate 2 are glass substrates.

Furthermore, refer to FIG. 2, the OLED element 21 comprises an anode conductive layer 211 located on the substrate 2, an organic layer 212 located on the anode conductive layer 211 and a cathode conductive layer 213 located on the organic layer 212.

step 2, as shown in FIG. 5, coating a circle of glass glue on the cover package plate 1, and forming frit glass 11 by high temperature presintering.

Specifically, screen print or dispensing is employed to coat the glass glue on the package cover plate 1.

step 3, as shown in FIG. 6, coating a circle of dryer 12 on the package cover plate 1 at an inner side of the frit glass 11 and at an outer side of the indentation 14, and curing the dryer 12 by low temperature baking.

The dryer 12 is polymer material containing absorbent composition. Preferably, a gap between the seal 12 and the frit glass 11 is larger than or equal to 500 um.

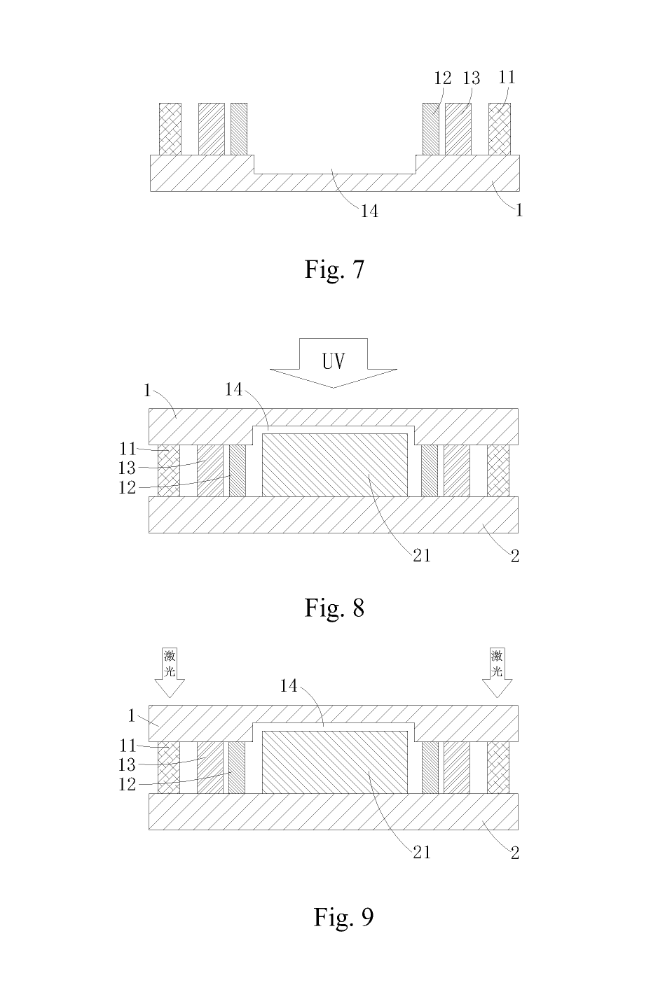

sep 4, as shown in FIG. 7, coating a circle of seal 13 at an inner side of the frit glass 11 and at an outer side of the dryer 12.

The seal 13 is UV curing glue. Preferably, a gap between the seal 13 and the frit glass 12 is smaller than or equal to 500 um.

step 5, as shown in FIG. 8, oppositely laminating the package cover plate 1 and the substrate 2 under a vacuum condition, and curing the seal 13 by UV irradiation.

step 6, as shown in FIG. 9, irradiating the seal area of the frit glass 11 by laser irradiation to melt the frit glass 11, and bonding the package cover plate 1 and the substrate 2 to accomplish the package of the package cover plate 1 to the substrate 2.

In the aforesaid OLED package method, as utilizing the frit glass to implement the package and meanwhile, the seal is coated at the inner side of the frit glass to increase the bonding area of the package cover plate and the substrate for reducing the dehiscence or the peeling of the glass glue caused by an internal residual stress as packaging, and mechanical strength is raised in advance. Meanwhile, the dryer filler is located at the periphery of the OLED element, which the package method applies to the OLED element packages of both top emitting type and bottom emitting type.

In conclusion, the OLED package structure utilizes the seal and the frit glass together to implement the package for possessing well tightness and mechanical strength at the same time, and meanwhile, the dryer filler is located at the periphery of the OLED element, which applies to the OLED element packages of both top emitting type and bottom emitting type. The OLED package method of the present invention utilizes the frit glass to implement the package and meanwhile, combines advantages of the seal for package. The seal can increase the bonding area of the package cover plate and the substrate for reducing the dehiscence or the peeling of the glass glue caused by an internal residual stress as packaging, and mechanical strength is raised in advance. Meanwhile, the dryer filler is located at the periphery of the OLED element, which the package method applies to the OLED element packages of both top emitting type and bottom emitting type.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An OLED package structure, comprising a package cover plate, a substrate, oppositely positioned with the package cover plate, an OLED element, positioned between the package cover plate and the substrate and set on the substrate, dryer, positioned at periphery of the OLED element between the package cover plate and the substrate, seal, positioned at periphery of the dryer to bond the package cover plate and the substrate and frit glass, located at periphery of the seal to bond the package cover plate and the substrate.

2. The OLED package structure according to claim 1, wherein the OLED element comprises an anode conductive layer located on the substrate, an organic layer located on the anode conductive layer and a cathode conductive layer located on the organic layer.

3. The OLED package structure according to claim 1, wherein an indentation is formed on the package cover plate corresponding to a location of the OLED element, and an internal space of the indentation accommodates a dimension of the OLED element.

4. The OLED package structure according to claim 1, wherein the dryer is polymer material containing absorbent composition, and a gap between the dryer and the frit glass is larger than or equal to 500 um.

5. The OLED package structure according to claim 1, wherein the seal is UV seal, and a gap between the seal and the dryer is smaller than or equal to 500 um.

6. An OLED package method, comprising steps of:
step 1, providing a package cover plate and a substrate;
an OLED element is located on the substrate, and an indentation is formed on the package cover plate corresponding to a location of the OLED element, and an internal space of the indentation accommodates a dimension of the OLED element;
step 2, coating a circle of glass glue on the cover package plate, and forming frit glass by high temperature presintering;
step 3, coating a circle of dryer on the package cover plate at an inner side of the frit glass and at an outer side of the indentation, and curing the dryer by low temperature baking;
step 4, coating a circle of seal at an inner side of the frit glass and at an outer side of the dryer;
step 5, oppositely laminating the package cover plate and the substrate under a vacuum condition, and curing the seal by UV irradiation;
step 6, melting the frit glass by laser irradiation, and bonding the package cover plate and the substrate to accomplish the package of the package cover plate to the substrate.

7. The OLED package method according to claim 6, wherein in the step 1, both the package cover plate and the substrate are glass substrates, and the OLED element comprises an anode conductive layer located on the substrate, an organic layer located on the anode conductive layer and a cathode conductive layer located on the organic layer.

8. The OLED package method according to claim 6, wherein in the step 2, screen print or dispensing is employed to coat the glass glue on the package cover plate.

9. The OLED package method according to claim 6, wherein in the step 3, the dryer is polymer material containing absorbent composition, and a gap between the dryer and the frit glass is larger than or equal to 500 um.

10. The OLED package method according to claim 6, wherein in the step 4, the seal is UV seal, and a gap between the seal and the dryer is larger than or equal to 500 um.

11. An OLED package structure, comprising a package cover plate, a substrate, oppositely positioned with the package cover plate, an OLED element, positioned between the package cover plate and the substrate and set on the substrate, dryer, positioned at periphery of the OLED element between the package cover plate and the substrate, seal, positioned at periphery of the dryer to bond the package cover plate and the substrate and frit glass, located at periphery of the seal to bond the package cover plate and the substrate.
wherein the OLED element comprises an anode conductive layer located on the substrate, an organic layer located on the anode conductive layer and a cathode conductive layer located on the organic layer.
wherein an indentation is formed on the package cover plate corresponding to a location of the OLED element, and an internal space of the indentation accommodates a dimension of the OLED element.

12. The OLED package structure according to claim 11, wherein the dryer is polymer material containing absorbent composition, and a gap between the dryer and the frit glass is larger than or equal to 500 um.

13. The OLED package structure according to claim 11, wherein the seal is UV seal, and a gap between the seal and the dryer is smaller than or equal to 500 um.
